(19) United States
(12) Patent Application Publication
(10) Pub. No.: US 2025/0201642 A1
(43) Pub. Date: Jun. 19, 2025

(54) SEMICONDUCTOR PACKAGE AND WIRING SUBSTRATE INCLUDED IN THE SAME, AND MANUFACTURING METHOD OF SEMICONDUCTOR PACKAGE

(71) Applicant: Samsung Electronics Co., Ltd., Suwon-si (KR)

(72) Inventor: Donggyu Kim, Suwon-si (KR)

(21) Appl. No.: 18/976,571

(22) Filed: Dec. 11, 2024

(30) Foreign Application Priority Data
Dec. 18, 2023 (KR) 10-2023-0184556

(51) Int. Cl. H01L 23/13; H01L 21/027; H01L 23/00; H01L 23/31; H01L 23/498; H01L 25/18; H05K 1/18; H10B 80/00

(52) U.S. Cl. CPC H01L 23/13; H01L 21/0274; H01L 23/49822; H01L 24/16; H01L 24/27; H01L 24/32; H01L 24/73; H05K 1/181; H01L 23/3128; H01L 24/48; H01L 24/49; H01L 25/18; H01L 2224/16227; H01L 2224/16238; H01L 2224/27312; H01L 2224/32145; H01L 2224/32225; H01L 2224/48091; H01L 2224/48225; H01L 2224/49175; H01L 2224/73204; H01L 2224/73257; H01L 2224/73265; H01L 2225/0651; H01L 2225/06517; H01L 2924/3656; H10B 80/00

(57) ABSTRACT

The present disclosure relates to a semiconductor package, a wiring substrate included in the same, and a manufacturing method of a semiconductor package. A semiconductor package according to an embodiment includes a wiring substrate having a first surface and a second surface opposite to each other, a semiconductor chip connected to the wiring substrate and positioned on the first surface of the wiring substrate, and an underfill layer between the wiring substrate and the semiconductor chip. The wiring substrate includes a wiring pattern, a solder resist layer including an opening exposing a portion of the wiring pattern at the first surface, and a dam protruding away from the wiring substrate at a region external to a lateral extent the semiconductor chip at the first surface. The solder resist layer further includes an uneven portion at a surface of the solder resist layer between the dam and the opening. The uneven portion is between the semiconductor chip and the dam in a plan view.

### CROSS-REFERENCE TO RELATED APPLICATION

This application claims priority to and the benefit of Korean Patent Application No. 10-2023-0184556 filed in the Korean Intellectual Property Office on Dec. 18, 2023, and all the benefits accruing therefrom under 35 U.S.C. 119, the entire contents of which are incorporated herein by reference.

### BACKGROUND

### (a) Field

The present disclosure relates to a semiconductor package, a wiring substrate included in the same, and a manufacturing method of a semiconductor package.

### (b) Description of the Related Art

Semiconductor devices may have a small size factor and may be configured to perform various functions and thus are widely used in various electronic industries. As advancements are made in the electronic industry, research on packaging technology has continued to reduce a size of the semiconductor devices and increase the performance of the semiconductor devices.

In the conventional art, bonding between a semiconductor chip and a wiring substrate depended on a chemical bonding force between the wiring substrate and a material bonded to the wiring substrate. Thus, a bonding property between the semiconductor chip and the wiring substrate might not be sufficient. Additionally, in a bonding process of the semiconductor chip and the wiring substrate, a flow of the material bonded to the wiring substrate might not be properly controlled, thereby reducing productivity and reliability of the semiconductor device.

### SUMMARY

The present disclosure attempts to provide a semiconductor package capable of enhancing productivity and reliability, a wiring substrate included in the same, and a manufacturing method of the semiconductor package.

A semiconductor package according to an embodiment includes a wiring substrate having a first surface and a second surface opposite to each other, a semiconductor chip connected to the wiring substrate and positioned on the first surface of the wiring substrate, and an underfill layer between the wiring substrate and the semiconductor chip. The wiring substrate includes a wiring pattern, a solder resist layer including an opening exposing a portion of the wiring pattern at the first surface, and a dam protruding away from the wiring substrate at a region external to a lateral extent of the semiconductor chip at the first substrate. The solder resist layer further includes an uneven portion at a surface of the solder resist layer between the dam and the opening. The uneven portion is between the semiconductor chip and the dam in a plan view.

A wiring substrate according to an embodiment has a first surface and a second surface opposite to each other. The wiring substrate includes a wiring pattern, a solder resist layer including an opening exposing a portion of the wiring pattern at a side of the first surface, and a dam protruding away from the wiring substrate at a region external to a lateral extent of the opening at the first surface. The solder resist layer further includes an uneven portion at a surface of the solder resist layer. The uneven portion is at an inside of the dam in a plan view.

A manufacturing method of a semiconductor package according to an embodiment includes forming a solder resist layer and forming an underfill layer. In the forming of the solder resist layer, the solder resist layer is formed on a wiring substrate. The solder resist layer includes an opening, a dam, and an uneven portion between the opening and the dam in a plan view. In the forming of the underfill layer, an underfill material is supplied between a semiconductor chip and the dam in a state in which the semiconductor chip and the wiring substrate are bonded using an interconnection member.

According to an embodiment, reliability and productivity of a semiconductor package including an underfill layer may be improved by a shape of the solder resist layer. More particularly, a bonding property with the underfill layer may be improved by an uneven portion, and an underfill material may be locked in the uneven portion and be prevented from overflowing to an outside of a dam. Accordingly, reliability may be improved. Further, an inner surface of a first resist portion adjacent to an opening area has a curved surface to reduce flow resistance of the underfill material and prevent a flow separation, thereby improving productivity and reliability.

### BRIEF DESCRIPTION OF THE DRAWINGS

FIG. 1 is a plan view schematically illustrating a semiconductor package according to an embodiment.

FIG. 2 is a cross-sectional view taken along line A-A′ in FIG. 1.

FIG. 3 is an enlarged partial cross-sectional view of portion B of FIG. 2.

FIG. 4A is a partially-cutout perspective view illustrating examples of uneven portions that are applicable to a semiconductor package according to an embodiment.

FIG. 4B is a partially-cutout perspective view illustrating examples of uneven portions that are applicable to a semiconductor package according to an embodiment.

FIG. 4C is a partially-cutout perspective view illustrating examples of uneven portions that are applicable to a semiconductor package according to an embodiment.

FIG. 5A is a cross-sectional view illustrating examples of uneven portions that are applicable to a semiconductor package according to an embodiment.

FIG. 5B is a cross-sectional view illustrating examples of uneven portions that are applicable to a semiconductor package according to an embodiment.

FIG. 5C is a cross-sectional view illustrating examples of uneven portions that are applicable to a semiconductor package according to an embodiment.

FIG. 6 illustrates a state of a semiconductor package during a manufacturing method of a semiconductor package according to an embodiment.

FIG. 7 illustrates a state of a semiconductor package during a manufacturing method of a semiconductor package according to an embodiment.

FIG. 8 illustrates a state of a semiconductor package during a manufacturing method of a semiconductor package according to an embodiment.

FIG. 9 illustrates a state of a semiconductor package during a manufacturing method of a semiconductor package according to an embodiment.

FIG. 10 illustrates a state of a semiconductor package during a manufacturing method of a semiconductor package according to an embodiment.

FIG. 11 illustrates a state of a semiconductor package during a manufacturing method of a semiconductor package according to an embodiment.

FIG. 12 illustrates a state of a semiconductor package during a manufacturing method of a semiconductor package according to an embodiment.

FIG. 13 illustrates a state of a semiconductor package during a manufacturing method of a semiconductor package according to an embodiment.

FIG. 14 illustrates a state of a semiconductor package during a manufacturing method of a semiconductor package according to an embodiment.

FIG. 15 is a plan view schematically illustrating a semiconductor package according to an embodiment.

FIG. 16 is a plan view schematically illustrating a semiconductor package according to an embodiment.

FIG. 17 is a cross-sectional view schematically illustrating a semiconductor package according to an embodiment.

FIG. 18 is a plan view schematically illustrating a semiconductor package according to an embodiment.

### DETAILED DESCRIPTION

Embodiments of the present disclosure will be described more fully hereinafter with reference to the accompanying drawings for those skilled in the art in which the present disclosure pertains to easily practice embodiments of the inventive concept described in the present disclosure. The inventive concept may be implemented in various different forms and is not limited to the embodiments provided herein.

The description of elements that are unrelated to the inventive concept may be omitted in order to clearly describe the present disclosure, and the same or similar components are denoted by the same reference numeral throughout the present specification.

Further, since sizes and thicknesses of portions, regions, members, units, layers, films, etc., shown in the accompanying drawings may be arbitrarily shown for better understanding and convenience of explanation, the present disclosure is not limited to the illustrated sizes and thicknesses. In the drawings, thicknesses of portions, regions, members, units, layers, films, etc., may be enlarged or exaggerated for convenience of explanation and/or simple illustration.

It will be understood that when a component such as a layer, film, region, or substrate is referred to as being “coupled”, “connected”, or “on” another component, it may be directly coupled, connected, or on the other component or an intervening component may also be present. In contrast, when a component is referred to as being “directly coupled,” “directly connected”, or “directly on” another component, there is no intervening component present. Further, when a component is referred to as being “on” a reference component, a component may be positioned above or below the reference component depending on the orientation of the component.

Spatially relative terms such as “beneath”, “below”, “lower”, “above”, “upper”, “top”, “bottom”, and the like, may be used herein for ease of description to describe positional relationships, such as illustrated in the figures, for example and are not necessarily related to a direction of gravity.

In addition, unless explicitly described to the contrary, the words “comprise”, “include”, or “contain”, and variations such as “comprises”, “comprising”, “includes”, “including”, “contains” or “containing” will be understood to imply the inclusion of other components rather than the exclusion of any other components.

Further, throughout the specification, the phrase “on a plane”, “in a plane”, “on a plan view”, or “in a plan view” may indicate a case where a portion is viewed from above or a top portion, and a phrase “on a cross-section” or “in a cross-sectional view” may indicate a vertical cross-sectional viewed from a side.

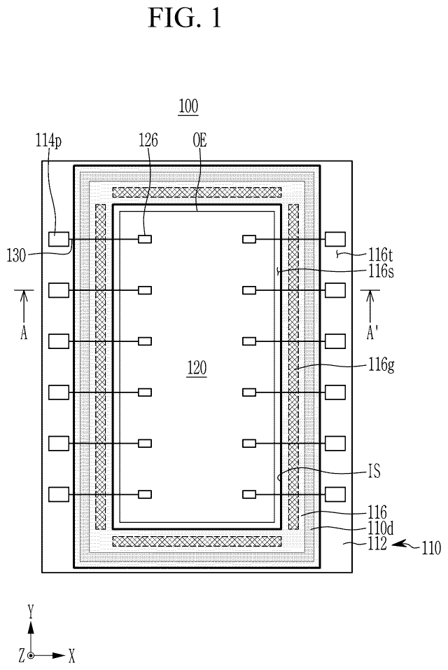

Hereinafter, a semiconductor package, a wiring substrate included in the same, and a manufacturing method of a semiconductor package according to an embodiment will be described in detail with reference to FIG. 1 to FIG. 12.

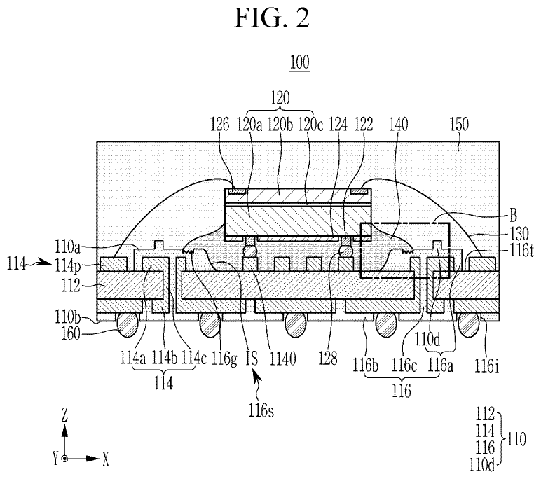

FIG. 1 is a plan view schematically illustrating a semiconductor package according to an embodiment. FIG. 2 is a cross-sectional view taken along line A-A′ in FIG. 1. For simple illustration and a clear understanding, an underfill layer 140 and a molding portion 150 are omitted in FIG. 1.

Referring to FIG. 1 and FIG. 2, a semiconductor package 100 according to an embodiment includes a wiring substrate 110, at least one semiconductor chip 120 connected to the wiring substrate 110, and an underfill layer 140 between the wiring substrate 110 and the at least one semiconductor chip 120 and may further include a molding portion 150.

As used herein, the singular forms “a”, “an” and “the” are intended to include the plural forms as well, unless the context clearly indicates otherwise. For example, the reference to at least one semiconductor chip 120 may include multiple semiconductor chips, such as a first semiconductor chip and a second semiconductor chip. As used herein, the term “and/or” includes any and all combinations of one or more of the associated listed items and may be abbreviated as “/”.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

In an embodiment, the wiring substrate 110 may include a first surface 110a (e.g., an upper surface) and a second surface 110b (e.g., a lower surface) that are opposite to each other. The at least one semiconductor chip 120 may be on the first surface 110a of the wiring substrate 110, and an external interconnection member 160 may be at the second surface 110b of the wiring substrate 110.

An interconnection member 128 included in the at least one semiconductor chip 120 may be at a lateral side of the first surface 110a of the wiring substrate 110, and the wiring substrate 110 and the at least one semiconductor chip 120 may be electrically connected to each other through the interconnection member 128. The semiconductor package 100 may be connected or coupled to an external circuit, an external device, a motherboard, or so on by the external interconnection member 160 at the second surface 110b of the wiring substrate 110. However, the embodiments are not limited thereto, and various modifications are possible.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes.

The external interconnection member 160 may have a land shape, a ball shape, a pin shape, or a bump shape. The external interconnection member 160 may be formed of and/or include at least one of tin, lead, bismuth, silver, copper, aluminum, tungsten, nickel, manganese, cobalt, titanium, tantalum, ruthenium, beryllium, indium, molybdenum, magnesium, rhenium, or gallium, or an alloy including the same. For example, the external interconnection member 160 may be formed of and/or include tin or an alloy including tin (e.g., a Sn—Ag based alloy, as an example, a Sn—Ag alloy, or a Sn—Ag based alloy including bismuth, copper, nickel, or so on). However, the embodiments are not limited thereto, and a shape, a material, or so on of the external interconnection member 160 may be variously modified.

The external interconnection member 160 may perform various functions according to a design. For example, the external interconnection member 160 may include an external interconnection member for ground, an external interconnection member for power, an external interconnection member for signal, or so on.

The wiring substrate 110 may include a base member 112 and a wiring pattern 114, a solder resist layer 116, and a dam 110d on the base member 112.

The base member 112 may structurally support the at least one semiconductor chip 120. The base member 112 may include any of various insulating materials, such as resin. The base member 112 may be formed using prepreg formed by impregnating glass fiber with resin. The resin of the base member 112 may be a thermosetting resin (such as an epoxy resin, a phenol resin, or so on) or a thermoplastic resin (such as polyether ketone, polyimide, or so on). However, a material of the base member 112 is not limited thereto and various modifications are possible.

The wiring pattern 114 may be on at least one of a first surface (e.g., upper surface) and a second surface (e.g., lower surface) of the base member 112. In an embodiment, the wiring pattern 114 may include a first wiring portion 114a on the first surface of the base member 112 and a second wiring portion 114b on the second surface of the base member 112. In addition, the wiring pattern 114 may include an extension portion 114c on an inner surface of a via included in the base member 112 to form a through contact. The extension portion 114c may connect the first wiring portion 114a and the second wiring portion 114b through the base member 112. The wiring pattern 114 may further include a connection pad 114p.

The wiring pattern 114 may perform various functions according to a design. For example, the wiring pattern 114 may include a ground pattern, a power pattern, a signal pattern, or so on. The signal pattern may be or include a pattern for transmitting various signals, e.g., data signals, or so on, except for signals applied to the ground pattern, the power pattern, or so on. The through contact may include a through contact for ground, a through contact for power, a through contact for signal, or so on.

The wiring pattern 114 (more particularly, the first wiring portion 114a, the second wiring portion 114b, the extension portion 114c, or the connection pad 114p) may be or include a plating layer. However, the embodiments are not limited thereto, and the wiring pattern 114 may be formed by any of various processes.

The wiring pattern 114 (more particularly, the first wiring portion 114a, the second wiring portion 114b, the extension portion 114c, or the connection pad 114p) may be formed of and/or include copper, aluminum, tungsten, nickel, gold, tin, manganese, cobalt, titanium, tantalum, ruthenium, or beryllium, or an alloy including the same. However, the embodiments are not limited thereto, and a material of the wiring pattern 114 may be variously modified.

In an embodiment, the first wiring portion 114a, the second wiring portion 114b, and the extension portion 114c of the wiring pattern 114 may be a part of the same layer and formed of the same material, and may be continuously connected (e.g., forming a single electrical node). However, the embodiments are not limited thereto. In some embodiments, at least one of the first wiring portion 114a and the second wiring portion 114b of the wiring pattern 114 may include a material different from the other. The connection pad 114p may be formed of the same material as or a different material from the first wiring portion 114a, the second wiring portion 114b, and/or the extension portion 114c. For example, the connection pad 114p may form a partial portion of the first wiring portion 114a. In some embodiments, the connection pad 114p may be formed separately from the first wiring portion 114a.

In the above description, the wiring substrate 110 has a two-layer wiring in which the wiring pattern 114 includes the first wiring portion 114a and the second wiring portion 114b. However, the embodiments are not limited thereto. In some embodiments, the wiring substrate 110 may have a single-layer wiring in which a wiring pattern 114 is formed on only one of the first surface and the second surface of the base member 112. In some embodiments, one or more base members may be on the base member 112, and the wiring pattern 114 may further include another wiring portion on the one or more base members. For example, the wiring pattern 114 may include three or more layers of wiring portions (e.g., fourth to sixth layers of wiring portions). In this case, the extended portion 114c of the wiring pattern 114 may connect at least two wiring portions among the three or more layers of wiring portions in a through contact.

The solder resist layer 116 may include a first resist portion 116a, a second resist portion 116b and a third resist portion 116c that may be continuously connected. The first resist portion 116a may be on the first wiring portion 114a on the first surface of the base member 112 or at the first surface 110a of the wiring substrate 110. The second resist portion 116b may be on the second wiring portion 114b on the second surface of the base member 112 or at the second surface 110b of the wiring substrate 110. In the drawing, it is illustrated that the solder resist layer 116 includes a through resist portion 116c at an inside of the through contact or the extension portion 114c, but the embodiments are not limited thereto. In some embodiments, the inside of the via may be entirely filled with the extension portion 114c. In such embodiments, through-resist portion 116c at the inside of the via or the extension portion 114c might not be included. Various other modifications are possible.

The first resist portion 116a may include an opening exposing at least a partial portion of the first wiring portion 114a. The opening may expose a partial portion of the first wiring portion 114a of the wiring substrate 110 so that the interconnection member 128 of the at least one semiconductor chip 120 may be connected to the first wiring portion 114a of the wiring substrate 110.

In an embodiment, the opening of the first resist portion 116a may be an opening area 116s that entirely exposes lands 1140 connected to interconnection members 128 of the at least one semiconductor chip 120. In the drawing, it is illustrated that the opening area 116s is in a center portion and the at least one semiconductor chip 120 is in a center portion of the wiring substrate 110 in a plan view. However, the embodiments are not limited thereto, and a position of the opening area 116s may be variously modified according to a shape, an arrangement, or so on of the at least one semiconductor chip 120.

In a plan view, the opening area 116s may extend laterally beyond an entire area of the at least one semiconductor chip 120, and an area of the opening area 116s may be greater than an area of the at least one semiconductor chip 120. Thereby, in a process of forming the underfill layer 140 using the opening area 116s, the underfill layer 140 may be stably formed using a space between the at least one semiconductor chip 120 and the wiring substrate 110. However, the embodiments are not limited thereto, and a position, or an area, or so on of the opening area 116s may be variously modified.

In some embodiments, an outer area 116t where the first resist portion 116a is not positioned may be in an area adjacent to an edge of the wiring substrate 110. In the outer area 116t, the first resist portion 116a may be entirely removed to expose the connection pad 114p in the area adjacent to the edge of the wiring substrate 110 for a connection of the at least one semiconductor chip 120 and the connection pad 114p. However, the embodiments are not limited thereto. In some embodiments, the first resist portion 116a may include openings exposing the connection pads 114p. The openings may correspond to the connection pads 114p in a one-to-one arrangement.

The second resist portion 116b may include openings 116i corresponding to the external interconnection members 160. For example, the openings 116i of the second resist portion 116b may correspond to the external interconnection members 160 in a one-to-one arrangement. Thereby, the second resist portion 116b may stably protect the second wiring portion 114b. However, the embodiments are not limited thereto, and a shape, an arrangement, or so on of the opening 116i may be variously modified.

A land 1140 where the interconnection member 128 of the at least one semiconductor chip 120 is positioned may be a portion of the first wiring portion 114a that is exposed through the opening area 116s of the first resist portion 116a. The land 1140 where the external interconnection member 160 is positioned may be a portion of the second wiring portion 114b exposed through the opening 116i of the second resist portion 116b. In order to improve a connection property with the interconnection member 128 or the external interconnection member 160, the land 1140 may have a pad shape and/or may include a layer (which may be in addition to other portions of wiring pattern 114) for enhancing a property of a surface where the interconnection member 128 or the external interconnection member 160 is positioned, or a surface treatment for enhancing a property may be performed to the surface where the interconnection member 128 or the external interconnection member 160 is positioned. However, the embodiments are not limited thereto, and the land 1140 may include the same shape or material as another portion.

The connection pad 114p to which a connecting member 130 is connected may be in a portion exposed through the outer area 116t of the first resist portion 116a. For example, the connecting member 130 may include a wire, and the connection pad 114p may include a wire bonding pad. However, the embodiments are not limited thereto. In some embodiments, the connecting member 130 and/or the connection pad 114p may not be included. For example, in embodiments in which the at least one semiconductor chip 120 is a single semiconductor chip and does not include a second semiconductor chip 120b or in embodiments in which the second semiconductor chip 120b is connected to the wiring substrate 110 by a structure other than the connecting member 130 (for example, by a flip chip structure), the connecting member 130 and the connecting pad 114p might not be included.

In an embodiment, the dam 110d may protrude from the first resist portion 116a at a region external to the at least one semiconductor chip 120 at the first surface 110a of the wiring substrate 110. The dam 110d may be a structure configured to prevent an underfill material from overflowing to an edge area adjacent to the edge of the wiring substrate 110 during a process of forming the underfill layer 140. The region external to the at least one semiconductor chip 120 may refer to a region or an area lateral to the at least one semiconductor chip 120 in a plan view at the first surface 110a of the wiring substrate 110. The region external to the at least one semiconductor chip 120 may include a portion of the opening area 116s where the at least one semiconductor chip 120 is not positioned, the first resist portion 116a, and the outer area 116t.

The dam 110d may be spaced apart from an inner surface IS and/or an inner edge ID of the first resist portion 116a adjacent to the at least one semiconductor chip 120 or the opening area 116s with a predetermined distance. The inner edge ID of the first resist portion 116a may refer to an inner edge at a surface (e.g., an upper surface) of the first resist portion 116a at the side of the first surface 110a of the wiring substrate 110.

More particularly, the entire dam 110d may be continuously formed and be spaced apart from an edge OE of the at least one semiconductor chip 120, the inner surface IS, and/or the inner edge ID of the first resist portion 116a with a predetermined distance. For example, in a plan view, the dam 110d may have a frame shape having an internal space and including four extension portions, and the at least one semiconductor chip 120 or the opening area 116s of the solder resist layer 116 may have a rectangular planar shape and may located in the internal space of the dam 110d as viewed in the plan view. As described in the above, the opening area 116s of the solder resist layer 116 may have a size or an area greater than a size of an area of the at least one semiconductor chip 120 in a plan view, and the inner surface IS or the inner edge ID of the first resist portion 116a may be between the edge OE of the at least one semiconductor chip 120 and an inner edge IE of the dam 110d.

However, the embodiments are not limited thereto. In some embodiments, the dam 110d may correspond to a partial portion of the inner surface IS or the inner edge ID of the first resist portion 116a or the at least one semiconductor chip 120. In some embodiments, entire the dam 110d might not be formed continuously and the dam 110d may instead be formed in discrete parts, so that the dam 110d has one or more cuts to form several partial portions. Various other modifications are possible.

In one embodiment, the dam 110d may be part of the solder resist layer 116 and may have a shape that protrudes from the first resist portion 116a in a cross-sectional view. That is, the dam 110d may be formed of the same material as the first resist portion 116a and be continuously connected (e.g., homogenous with) to the first resist portion 116a to have an integral structure with the first resist portion 116a (e.g., the dam 110d and the solder resist). The dam 110d also may be solder resist, and in this instance, formed at the same time as the solder resist layer 116 from a solder resist material formed in a single deposition process (e.g., formed in a sealed chamber that does not experience a vacuum break during the deposition process). However, the embodiments are not limited thereto. In some embodiments, the dam 110d may include a different material from the first resist portion 116a or may be formed in a separate process from the first resist portion 116a.

In an embodiment, an uneven portion 116g may be formed at one surface (e.g., the upper surface) of the solder resist layer 116 at the first surface 110a of the wiring substrate 110. The inner surface IS of the first resist portion 116a adjacent to the opening area 116s may include a curved surface. The uneven portion 116g and the inner surface IS of the first resist portion 116a will be described in more detail later.

The solder resist layer 116 may be formed by applying an ink material or by placing a film and then performing an exposure process and/or a development process. A manufacturing process of the solder resist layer 116 including the dam 110d and the uneven portion 116g will be described in detail later in a manufacturing method of a semiconductor package 100.

For example, the wiring substrate 110 may be a printed circuit board (PCB). However, the embodiments are not limited thereto. Accordingly, the wiring substrate 110 may be a redistribution portion, a redistribution substrate, an interposer, a connection board, or so on.

In an embodiment, the at least one semiconductor chip 120 may be a memory chip that stores data, a non-memory chip that calculates, processes, or controls information, or a merged semiconductor chip in which a memory portion and a non-memory portion are combined. In other examples, rather than a single semiconductor chip, a plurality of chips may be used. For example, at least one semiconductor chip 120 may represent one or more memory chips and may also include one or more non-memory chips. The memory chip(s) may be volatile memory (such as dynamic random access memory (DRAM), static random access memory (SRAM), or so on), or non-volatile memory (such as NAND flash memory system or so on). For example, the non-memory chip(s) (as well as the merged semiconductor chip) may include a central processing unit (CPU), a graphic processing unit (GPU), a neural processing unit (NPU), and a microcontroller unit (MCU), an application processor (AP), a field programmable gate array (FPGA), an application-specific integrated circuit (ASIC), or so on. As such, the embodiments are not limited to a type, a kind, or so on of at least one semiconductor chip 120.

A semiconductor device portion including various circuit elements may be at one surface of the at least one semiconductor chip 120 (more particularly, a first semiconductor chip 120a in embodiments in which there are multiple semiconductor chips in the at least one semiconductor chip 120). The circuit elements may include active elements (such as a transistor or so on and passive elements (such as a capacitor, a resistor, an inductor, or so on). In addition, the semiconductor device portion may further include a conductive wiring or a conductive plug that electrically connects the circuit elements, and an insulating layer that electrically insulates the conductive wiring, the conductive plug, and/or the circuit elements that should be insulated from each other.

A pad 122 electrically connected to the semiconductor device portion and an insulating layer 124 may be on one surface of the at least one semiconductor chip 120 (more particularly, the first semiconductor chip 120a). One surface of the first semiconductor chip 120a or the pad 122 and the insulating layer 124 may face the first surface 110a of the wiring substrate 110. The pad 122 may include a pad portion or may have a structure in which an under bump metal (UBM) is coupled to the pad portion. The insulating layer 124 may include any of various insulating materials.

In FIG. 2, it is illustrated as an example that a thickness of the pad 122 is greater than a thickness of the insulating layer 124 in a thickness direction (a Z-axis direction in the drawing) and thus the pad 122 protrudes than the insulating layer 124. In FIG. 2, it is illustrated as an example that an area of the pad 122 is less than an area of an opening of the insulating layer 124 and the pad 122 is spaced apart from the insulating layer 124, and the interconnection member 128 is on a protruded portion of the pad 122 and is not between the insulating layer 124 and the pad 122 or on the insulating layer 124. However, the embodiments are not limited thereto. In some embodiments, the thickness of the pad 122 may be the same as or less than the thickness of the insulating layer 124 in the thickness direction (the Z-axis direction in the drawing). In some embodiments, the area of the pad 122 may be the same as or greater than the area of the opening of the insulating layer 124, or the pad 122 may be in contact with a side surface or an outer surface of the insulating layer 124. In some embodiments, the interconnection member 128 may be on the side surface or the outer surface of the insulating layer 124, or between the pad 122 and the insulating layer 124. Various other modifications are possible.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

The pad 122 may be formed of and/or include at least one of copper, aluminum, tungsten, nickel, gold, tin, manganese, cobalt, titanium, tantalum, ruthenium, or beryllium, or an alloy including the same. However, the embodiments are not limited thereto, and a material of the pad 122 may be variously modified.

An insulating material of the insulating layer 124 may include any of various compounds or any of various resins. For example, the insulating layer 124 may be formed of and/or include an insulating material of a compound such as oxide, nitride, or oxynitride. In some embodiments, the insulating layer 124 includes a thermosetting resin (such as an epoxy resin), a thermoplastic resin (such as polyimide), a resin including an inorganic filler and/or glass fiber, or a photosensitive resin (such as a photoimageable dielectric (PID) material, photosensitive polyimide (PSPI), or so on). The insulating layer 124 may include a single layer or a plurality of layers. When the insulating layer 124 includes the plurality of layers, a boundary between the plurality of layers might not be perceivable depending on a process. Accordingly, the insulating layer 124 may have any of various materials and any of various stacked structures.

The interconnection member 128 may have a land shape, a ball shape, a pin shape, or a bump shape. When the interconnection member 128 and the external interconnection member 160 have the bump shapes, the interconnection member 128 may be a fine bump smaller than the external interconnection member 160, but the embodiments are not limited thereto.

The interconnection member 128 may be formed of and/or include at least one of tin, lead, bismuth, silver, copper, aluminum, tungsten, nickel, manganese, cobalt, titanium, tantalum, ruthenium, beryllium, indium, molybdenum, magnesium, rhenium, or gallium, or an alloy including the same. For example, the interconnection member 128 may be formed of and/or include tin or an alloy including tin (e.g., a Sn—Ag based alloy, as an example, a Sn—Ag alloy, or a Sn—Ag based alloy including copper or so on). The interconnection member 128 may include a material that is the same as a material of the external interconnection member 160 or may include a material that is different from the material of the external interconnection member 160. A shape, a material, or so on of the interconnection member 128 may be variously modified.

In an embodiment, the at least one semiconductor chip 120 may include a first semiconductor chip 120a and a second semiconductor chip 120b on the first semiconductor chip 120a. The second semiconductor chip 120b may be bonded to the first semiconductor chip 120a using an adhesive layer 120c. By stacking the second semiconductor chip 120b on the first semiconductor chip 120a, a size or an area of the semiconductor package 100 may be reduced.

In such embodiments, the first semiconductor chip 120a may have a flip chip structure that is electrically connected to the wiring substrate 110 using the interconnection member 128, and the second semiconductor chip 120b may have a wire bonding structure that is electrically connected to the wiring substrate 110 using the connecting member 130. For example, a chip pad 126 may be on an upper surface of the second semiconductor chip 120b, and the chip pad 126 of the second semiconductor chip 120b and the connection pad 114p of the wiring substrate 110 may be electrically connected to each other through the connecting member 130.

For example, the first semiconductor chip 120a may include a non-memory chip (e.g., a logic chip). For example, the first semiconductor chip 120a may include a central processing unit (CPU), a graphic processing unit (GPU), a neural network processing unit (NPU), a microcontroller unit (MCU), an application processor (AP), a field programmable gate array (FPGA), an application specific semiconductor (ASIC), or so on. The second semiconductor chip 120b may include a memory chip. For example, the second semiconductor chip 120b may include a dynamic random access memory (DRAM), a static random access memory (SRAM), a NAND flash memory system, or so on.

However, the embodiments are not limited thereto. In some embodiments, the at least one semiconductor chip 120 may include a single semiconductor chip. In some embodiments, the second semiconductor chip 120b may be at a separate position from the first semiconductor chip 120a in a plan view (e.g., the second semiconductor chip 120b may be lateral to the first semiconductor chip 120a). This will be explained in more detail later.

In the drawing, it is illustrated as an example that the first semiconductor chip 120a and the second semiconductor chip 120b have the same area or size, but the embodiments are not limited thereto. The second semiconductor chip 120b may have an area or a size less than or greater than an area or a size of the first semiconductor chip 120a.

The underfill layer 140 may be between the at least one semiconductor chip 120 (more particularly, the first semiconductor chip 120a) and the wiring substrate 110 to surround the interconnection member 128. The underfill layer 140 may protect the interconnection member 128, and a bonding property of the at least one semiconductor chip 120 and the wiring substrate 110 may be improved by chemical bonding between the underfill layer 140 and the solder resist layer 116.

The underfill layer 140 may include a thermosetting resin (such as an epoxy resin), a thermoplastic resin (such as polyimide), a resin including an inorganic filler or/and glass fiber, an epoxy molding compound (EMC), or so on, but the embodiments are not limited to these materials. The underfill layer 140 may include a material that is the same as a material of the molding portion 150 or may include a material that is different from the material of the molding portion 150. A shape, a material, or so on of the underfill layer 140 may be variously modified.

The molding portion 150 may mold around the at least one semiconductor chip 120. For example, the molding portion 150 may cover or surround at least a side surface and an upper surface of the at least one semiconductor chip 120 and may cover the first surface 110a of the wiring substrate 110. In some embodiments, the molding portion 150 may include a single layer or a plurality of layers. The molding portion 150 may include a thermosetting resin (such as an epoxy resin), a thermoplastic resin (such as polyimide), a resin including an inorganic filler or/and glass fiber, or a molding material (such as an epoxy molding compound or so on). A shape, a material, or so on of the molding portion 150 may be variously modified.

In an embodiment, the wiring substrate 110 may have a first length in a first direction (an X-axis direction in the drawing), may have a second length in a second direction (a Y-axis direction in the drawing) that is transverse to (e.g., perpendicular to) the first direction, and may have a predetermined thickness in a thickness direction (the Z-axis direction in the drawing). The second length may be greater than the first length. The at least one semiconductor chip 120 may have a size or an area less than a size or an area of the wiring substrate 110. The at least one semiconductor chip 120 may have a third length less than the first length in the first direction, may have a fourth length less than the second length in the second direction, and may have a predetermined thickness in the thickness direction (the Z-axis direction in the drawing). In some embodiments, the fourth length may be greater than the third length. The opening area 116s of the solder resist layer 116 may have a size or an area less than a size or an area of the at least one semiconductor chip 120. The opening area 116s of the solder resist layer 116 may have a fifth length less than the first direction and greater than the third length in the first direction, may have a sixth length less than the second length and greater than the fourth length in the second direction. In some embodiments, the sixth length may be greater than the fifth length. In some embodiments, the edge OE of the at least one semiconductor chip 120 may be spaced apart from the edge of the wiring substrate 110 by a predetermined distance, and an edge of the opening area 116s may be spaced apart from the edge OE of the at least one semiconductor chip 120 by a predetermined distance. The described sizing may enhance the structural stability of the semiconductor package 100.

However, the embodiments are not limited thereto. In some embodiments, the wiring substrate 110 may have the same length in the first direction and the second direction, the at least one semiconductor chip 120 may have the same length in the first direction and the second direction, or the opening area 116s may have the same length in the first direction and the second direction. In some embodiments, there are portions where distances between the edge of the wiring substrate 110 and the edge OE of the at least one semiconductor chip 120 are different from each other. In some embodiments, there are portions where distances between the edge OE of the at least one semiconductor chip 120 and the edge of the opening area 116s are different from each other. In some embodiments, at least two of a long axis direction of the wiring substrate 110, a long axis direction of the at least one semiconductor chip 120, and a long axis direction of the opening area 116s may be different from each other. Various other modifications are possible.

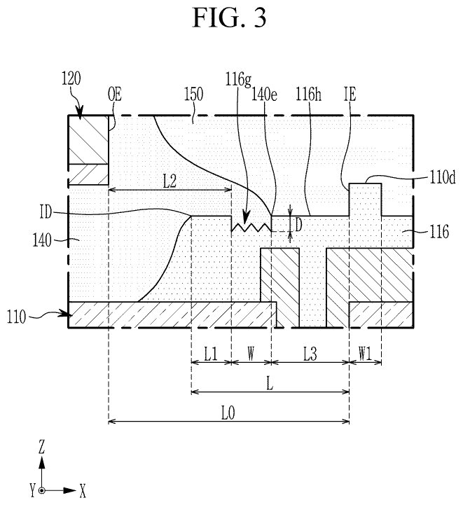

Referring to FIG. 3 to FIG. 5 together with FIG. 1 and FIG. 2, the uneven portion 116g at the solder resist layer 116 and the inner surface IS of the first resist portion 116a adjacent to the opening area 116s according to the embodiment will be explained in more detail.

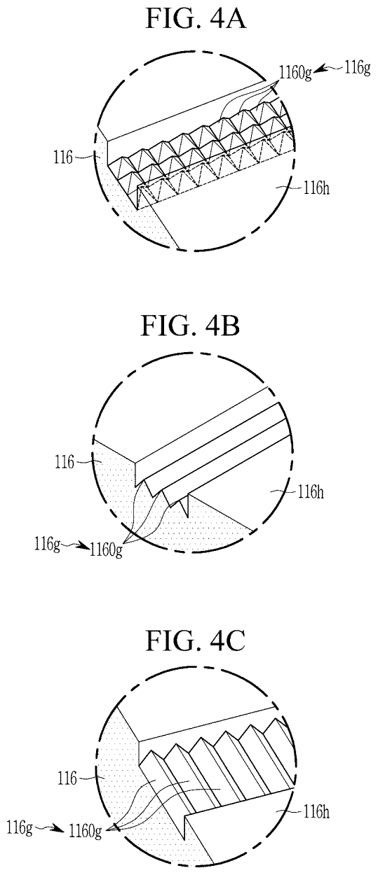

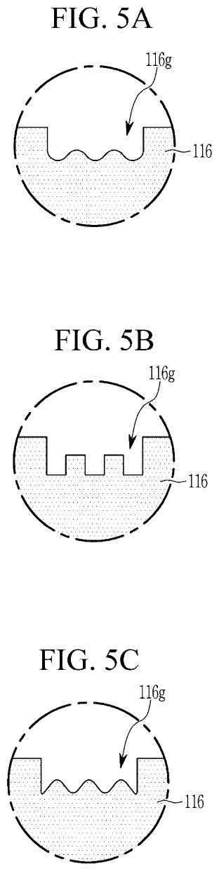

FIG. 3 is an enlarged partial cross-sectional view of portion B of FIG. 2. FIG. 4 is a partially-cut perspective view illustrating examples of uneven portions 116g that are applicable to in a semiconductor package according to an embodiment. FIG. 5 is a cross-sectional view illustrating examples of uneven portions 116g of a semiconductor package 100 according to an embodiment.

Referring to FIG. 1 to FIG. 5, in an embodiment, the uneven portion 116g may be at the solder resist layer 116. More particularly, the uneven portion 116g may be at one surface (e.g., an upper surface) of the first resist portion 116a at the side of the first surface 110a of the wiring substrate 110.

The uneven portion 116g may be a portion having a surface roughness greater than a surface roughness of a base surface 116h of the first resist portion 116a and may have a surface area per unit area greater than a surface area per unit area of the base surface 116h. The base surface 116h may refer to a surface of the first resist portion 116a where the uneven portion 116g and the dam 110d are not formed at the first surface 110a of the wiring substrate 110. A contact area between the first resist portion 116a and the underfill layer 140 may be increased (as compared to a flat portion) by the uneven portion 116g (e.g., due to the greater surface area per unit area), and thus, the uneven portion 116g may be referred to as a contact-area enlargement portion.

For example, the surface roughness of the uneven portion 116g May be 10 μm or less (for example, 1 μm to 10 μm). If the surface roughness of the uneven portion 116g is greater than 10 μm, the process time of forming the uneven portion 116g may increase and the process of forming the uneven portion 116g may have an undesirable effect on the wiring pattern 114. When the surface roughness of the uneven portion 116g is 1 μm or more, the effect of the uneven portion 116g may be effectively achieved. However, the embodiments are not limited thereto, and in some embodiments, the surface roughness of the uneven portion 116g may be greater than 10 μm or be less than 1 um. Various other modifications are possible.

The uneven portion 116g may be formed by etching or removing a partial portion of the first resist portion 116a, and thus, a lower surface or a bottom surface of the uneven portion 116g may be lower than the base surface 116h. Accordingly, the uneven portion 116g may be referred to as an etched portion, a concave portion, a recessed portion, an indented portion, grooves, or so on. Since the lower surface or the bottom surface of the uneven portion 116g is lower than the base surface 116h, the underfill layer 140 may be locked in an internal space of the uneven portion 116g. Accordingly, in a process of forming the underfill layer 140, the uneven portion 116g may guide the underfill material to flow in an internal direction (i.e., toward a lower portion of the at least one semiconductor chip 120) rather than in an external direction (i.e., toward the dam 110d) (e.g., the uneven portion 116g may inhibit the underfill material from flowing past the uneven portion 116g).

The contact surface area between the solder resist layer 116 and the underfill layer 140 may be increased by the uneven portion 116g, thereby improving a physical bonding force between the solder resist layer 116 and the underfill layer 140. For example, when the solder resist layer 116 and the underfill layer 140 including different materials are bonded, a bonding property may be improved by using not only the chemical bonding force of the solder resist layer 116 and the underfill layer 140 but also the physical bonding force of the solder resist layer 116 and the underfill layer 140. In this instance, in the process of forming the underfill layer 140, a flow of the underfill material may depend on a viscosity, a flow rate, or so on of the underfill material and may be unrelated to the friction coefficient. Therefore, when the uneven portion 116g is formed, the uneven portion 116g does not block or impede the flow of the underfill material.

In the process of forming the underfill layer 140, the uneven portion 116g may guide or bias the underfill material to flow in an internal direction (e.g., towards the semiconductor chip 120) and may prevent the underfill material from flowing over the dam 110d to the edge area. Thereby, problems such as contamination of the connection pad 114p by the underfill material may be prevented.

In the conventional art, a bonding property of a semiconductor chip and a wiring substrate depended only on a chemical bonding force of an underfill layer and a solder resist layer, and thus, a bonding property of the underfill layer and the solder resist layer might not be sufficient. Further, in the process of forming the underfill layer, the underfill material may flow over a dam and overflow into an edge area. In this instance, a connection pad located outside of the dam may be contaminated.

In an embodiment, the uneven portion 116g may be inside of the dam 110d in a plan view. For example, the uneven portion 116g may be partially or locally provided between the at least one semiconductor chip 120 and the dam 110d in a plan view.

In a plan view, a width W of the uneven portion 116g may be less than a distance L0 between the at least one semiconductor chip 120 and the dam 110d. The width W of the uneven portion 116g may refer to a minimum width of the uneven portion 116g in a direction that is transverse to (for example, perpendicular to) an extension direction of the uneven portion 116g. The distance L0 between the at least one semiconductor chip 120 and the dam 110d may refer to a distance between the edge OE of the at least one semiconductor chip 120 and the inner edge IE of the dam 110d and may refer to a minimum distance.

In a plan view, the width W of the uneven portion 116g may be less than an inner distance L between the inner edge ID of the first resist portion 116a adjacent to the opening area 116s and the inner edge IE of the dam 110d. The inner distance L may refer to a distance between the inner edge ID of the first resist portion 116a adjacent to the opening area 116s at one surface (e.g., an upper surface) of the first resist portion 116a and the dam 110d and may refer to a minimum distance.

For example, in a plan view, the uneven portion 116g of the solder resist layer 116 may be spaced apart from the inner edge ID of the first resist portion 116a adjacent to the opening area 116s. More particularly, the inner edge of the uneven portion 116g may be spaced apart from the inner edge ID of the first resist portion 116a at one surface (e.g., an upper surface) of the first resist portion 116a adjacent to the first surface 110a of the wiring substrate 110.

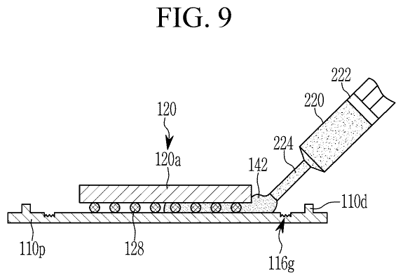

That is, a first distance L1 between the inner edge of the uneven portion 116g and the inner edge ID of the first resists portion 116a at one surface (e.g., an upper surface) of the first resist portion 116a may be greater than zero (0) (e.g., 1 μm to 200 um). As a result, the uneven portion 116g may not adversely affect the process of forming the underfill layer 140. For example, the first distance L1 may be greater than a size (e.g., a diameter) of a nozzle 224 (refer to FIG. 9) of a dispenser 220 (refer to FIG. 9) injecting the underfill material in the process of forming the underfill layer 140.

For example, in a plan view, the uneven portion 116g of the solder resist layer 116 may be spaced apart from the edge OE of the at least one semiconductor chip 120. More particularly, a second distance L2 between the inner edge of the uneven portion 116g and the edge OE of the at least one semiconductor chip 120 may be greater than zero (0). As a result, the uneven portion 116g may not adversely affect the process of forming the underfill layer 140.

In an embodiment, in a plan view, the uneven portion 116g of the solder resist layer 116 may be spaced apart from the inner edge IE of the dam 110d. More particularly, a third distance L3 between an outer edge of the uneven portion 116g and the inner edge IE of the dam 110d may be greater than zero (0).

However, the embodiments are not limited thereto. In a plan view, at least a partial portion of the uneven portion 116g of the solder resist layer 116 may be adjacent to the inner edge IE of the dam 110d. More particularly, the third distance L3 between the outer edge of the uneven portion 116g and the inner edge IE of the dam 110d may be zero (0). When the uneven portion 116g is adjacent to the inner edge IE of the dam 110d, the uneven portion 116g may have a sufficient area or width W.

For example, the third distance L3 may be less than the second distance L2. Then, the process of forming the underfill layer 140 may be stably performed and the uneven portion 116g may have the sufficient area or width W. In some embodiments, the third distance L3 may be the same as or greater than the second distance L2. Then, the underfill material may be effectively prevented from overflowing to the outside of the dam 110d in the process of forming the underfill layer 140.

For example, the third distance L3 may be less than the first distance L1. Then, the process of forming the underfill layer 140 may be stably performed and the uneven portion 116g may have the sufficient area or width W. In some embodiments, the third distance L3 may be the same as or greater than the first distance L1. Then, the underfill material may be effectively inhibited from overflowing to the outside of the dam 110d in the process of forming the underfill layer 140.

In an embodiment, the width W of the uneven portion 116g may be greater than a depth D of the uneven portion 116g. The depth D of the uneven portion 116g may refer to a maximum height difference between the lower surface of the bottom surface of the uneven portion 116g and the base surface 116h and may refer to a surface roughness (e.g., a maximum surface roughness). According to this, the width W of the uneven portion 116g may be sufficiently secured and thus the effect of the uneven portion 116g may be effectively achieved. However, the embodiments are not limited thereto. Therefore, the width W of the uneven portion 116g may be the same as or less than the depth D of the uneven portion 116g. Then, the depth D of the uneven portion 116g may be sufficiently secured and thus the underfill layer 140 may be effectively locked in the uneven portion 116g.

The width W of the uneven portion 116g may be greater than a width W1 of the dam 110d. The width W1 of the dam 110d may refer to a minimum width of the dam 110d in a direction that is transverse to (e.g., perpendicular to) an extension direction of the dam 110d. According to this, the depth D of the uneven portion 116g may be sufficiently secured and thus the underfill layer 140 may be effectively locked in the uneven portion 116g. However, the embodiments are not limited thereto. Therefore, the width W of the uneven portion 116g may be the same as or less than the width W1 of the dam 110d. Then, the width W1 of the dam 110d may be sufficiently secured to inhibit the underfill material from flowing over the dam 110d and overflowing to the edge area in the forming process of the underfill layer 140.

For example, the width W of the uneven portion 116g may be less than 1 mm. More particularly, the width W of the uneven portion 116g may be 1 μm to 900 um (e.g., 100 μm to 800 um). When the width W of the uneven portion 116g is 1 μm or more (e.g., 100 μm or more), an area of the uneven portion 116g may be sufficiently secured and the underfill layer 140 may be effectively locked in the uneven portion 116g. If the width W of the uneven portion 116g is 1 mm or more, it may be difficult to easily control the flow of the underfill material in the process of forming the underfill layer 140. However, the embodiments are not limited thereto, and the width W of the uneven portion 116g may be less than 1 μm or greater than 1 mm.

In an embodiment, the uneven portion 116g may include a plurality of uneven sections. The plurality of uneven sections may extend in a direction parallel to the edge OE of the at least one semiconductor chip 120 or in a direction parallel to the inner surface IS or the inner edge ID of the first resist portion 116a adjacent to the opening area 116s. The plurality of uneven sections may be spaced apart from the edge OE of the at least one semiconductor chip 120, or the inner surface IS or the inner edge ID of the first resist portion 116a adjacent to the opening area 116s by a predetermined distance. For example, the plurality of uneven sections may be spaced apart from each other by a predetermined distance at a corner portion of the at least one semiconductor chip 120 or the opening area 116s. However, the embodiments are not limited thereto. In some embodiments, a plurality of uneven sections constituting the uneven portion 116g may be connected at corner portions and thus the uneven portion 116g may have a frame shape having a rectangular planar shape.

In an embodiment, the uneven portion 116g may have a symmetrical shape when viewed in one direction.

For example, a pair of uneven sections may be at both sides of the at least one semiconductor chip 120 in the first direction (the X-axis direction in the drawing) to be spaced apart from both edges of the at least one semiconductor chip 120 in the first direction. Distances between both edges of the at least one semiconductor chip 120 and the pair of uneven sections may be the same, and lengths of the pair of uneven sections in the second direction (the Y-axis direction in the drawing) that is transverse the first direction may be the same.

For example, a pair of uneven sections spaced apart from each other may be at both edges of the at least one semiconductor chip 120 in the second direction (the Y-axis direction in the drawing) to be spaced apart from both edges of the at least one semiconductor chip 120 in the second direction. Distances between both edges of the at least one semiconductor chip 120 and the pair of uneven sections may be the same, and lengths of the pair of uneven sections in the first direction (the X-axis direction in the drawing) that is transverse the second direction may be the same.

In the process of forming the underfill layer 140, the underfill material may be injected from a first side of the at least one semiconductor chip 120 and moved toward a second side of the at least one semiconductor chip 120 in one direction. By the pair of uneven sections at the first side where the underfill material is injected and the second side that is opposite to the first side, the underfill material may be inhibited from flowing over the dam 110d and overflowing to the edge area at the first side and the second side in the forming process of the underfill layer 140. In FIG. 1, it is illustrated as an example that the uneven portions 116g or the uneven sections are in each of the first direction and the second direction that are transverse to each other and are in each of a short axis direction and a long axis direction that are transverse to each other. According to this, even when underfill materials are injected together in directions that are transverse to each other in the process of forming the underfill layer 140, the underfill material may be effectively prevented from flowing over the dam 110d and overflowing to the edge area. However, the embodiments are not limited thereto. Even when the uneven portions 116g have the structure illustrated in FIG. 1, the underfill material may be injected in one direction in the process of forming the underfill layer 140. Other shapes of the uneven portion 116g or of the uneven section will be described in more detail later.

In an embodiment, an outer edge 140e of the underfill layer 140 may be adjacent to the uneven portion 116g. This may be because the nozzle 224 (refer to FIG. 9) of the dispenser 220 (refer to FIG. 9) that injects the underfill material is located between the at least one semiconductor chip 120 and the uneven portion 116g in the process of forming the underfill layer 140. For example, the outer edge 140e of the underfill layer 140 may be at an inside of the uneven portion 116g or may be between the uneven portion 116g and the dam 110d so that the outer edge 140e of the underfill layer 140 is spaced apart from the inner edge of the dam 110d. However, the embodiments are not limited thereto, and at least a partial portion of the outer edge 140e of the underfill layer 140 may be adjacent to the dam 110d.

In FIG. 3, it is illustrated as an example that an outer surface of the uneven portion 116g includes an inclined surface inclined to the base surface 116h or the base member 112 and the uneven portion 116g has a triangular cross-sectional shape.

For example, as illustrated in FIG. 4A, the uneven portion 116g may include an uneven member 1160g. The uneven member 1160g has a triangular cross-sectional shape in a plane perpendicular to one direction and has a triangular cross-sectional shape in a plane perpendicular to another direction that is transverse to (e.g., perpendicular to) the one direction to have a pyramid shape. In some embodiments, as illustrated in FIG. 4B, the uneven portion 116g may include an uneven member 1160g. The uneven member 1160g has a triangular cross-sectional shape in a plane perpendicular to an extension direction of the uneven portion 116g and extend in the extension direction of the uneven portion 116g. In some embodiments, as illustrated in FIG. 4C, the uneven portion 116g may include an uneven member 1160g. The uneven member 1160g has a triangular cross-sectional shape in a plane perpendicular to a transverse direction that is transverse to (e.g., perpendicular to or inclined to) an extension direction of the uneven portion 116g and extends in the transverse direction of the uneven portion 116g.

In some embodiments, as illustrated in FIG. 5A, the uneven portion 116g may include an uneven structure having an overall rounded shape or having an overall curved surface. The uneven structures of the uneven portion 116g may be repeated in each of directions that are transverse to each other or may extend in an extension direction of the uneven portion 116g or in a direction that is transverse to the extension direction of the uneven portion 116g. In some embodiments, as illustrated in FIG. 5B, the uneven portion 116g may include an uneven structure having a polygonal cross-sectional shape (e.g., a rectangular cross-sectional shape) having a side surface that is inclined or perpendicular to the base surface 116h or the base member 112. The uneven structures of the uneven portion 116g may be repeated in each of directions that are transverse to each other or may extend in an extension direction of the uneven portion 116g or in a direction that is transverse to the extension direction of the uneven portion 116g.

In some embodiments, as illustrated in FIG. 50, the uneven portion 116g may include an uneven structure having both of a flat portion and a curved portion or having a cross-sectional shape including both of a straight portion and a curved portion. The uneven structures of the uneven portion 116g may be repeated in each of directions that are transverse to each other or may extend in an extension direction of the uneven portion 116g or in a direction that is transverse to the extension direction of the uneven portion 116g.

In FIG. 3 to FIG. 5, it is illustrated as an example that the plurality of uneven portions 116g have substantially the same size, the same cross-sectional shape, and a regular arrangement. However, the embodiments are not limited thereto. Accordingly, a plurality of structures included in the uneven portion 116g may have different sizes, different cross-sectional shapes, irregular shapes, or irregular arrangements. Various other modifications are possible.

Referring to FIG. 3, the inner surface IS of the first resist portion 116a adjacent to the opening area 116s may have a curved surface. For example, the inner surface IS of the first resist portion 116a may be or include a rounded surface formed through a rounding process. For example, the inner surface IS of the first resist portion 116a may be convex upward at an upper portion or a portion adjacent to the dam 110d and may be convex downward at a lower portion or a portion adjacent to the at least one semiconductor chip 120. Then, in the process of forming the underfill layer 140, the underfill material may be allowed to flow stably on the inner surface IS of the first resist portion 116a. However, the embodiments are not limited thereto. In some embodiments, the inner surface IS of the first resist portion 116a may be entirely convex upward or entirely convex downward. In some embodiments, the inner surface IS of the first resist portion 116a may include an inclined surface having an obtuse angle with the base surface 116h of the first resist portion 116a.

When the inner surface IS of the first resist portion 116a adjacent to the opening area 116s has the curved surface or the inclined surface, a flow separation (such as a void or so on) at a portion adjacent to the inner surface IS of the first resist portion 116a may be prevented. Further, flow resistance may be reduced by preventing pressure loss in the injection process of the underfill material that may occur at the portion adjacent to the inner surface IS of the first resist portion 116a. Accordingly, the underfill material may move widely in the injection process of the underfill material, thereby reducing a number of the injection process of the underfill material.

Conventionally, an inner surface of a first resist portion adjacent to an opening area is a vertical surface perpendicular to a base surface of a first resist portion and there is a portion where an underfill material flows along the vertical surface. The friction coefficient of the underfill material may increase at a portion adjacent to the inner surface of the first resist portion, and thus, there may be a large friction loss and a flow separation (such as a void or so on) may easily occur.

The uneven portion 116g of the solder resist layer 116 and the inner surface IS of or the first resist portion 116a having the rounded shape according to embodiments may be confirmed through a cross-sectional or planar photograph or a surface analysis.

According to an embodiment, reliability and productivity of the semiconductor package 100 including the underfill layer 140 may be improved by a shape of the solder resist layer 116. More particularly, a bonding property of the underfill layer 140 and the first solder resist portion 116a may be improved by the uneven portion 116g, and the underfill material may be locked in the uneven portion 116g and be prevented from overflowing to the outside of the dam 110d. Accordingly, reliability may be improved. Further, the inner surface IS of the first resist portion 116a adjacent to the opening area 116s has a curved surface to reduce flow resistance of the underfill material and prevent a flow separation, thereby improving productivity and reliability of the process of forming the underfill layer 140.

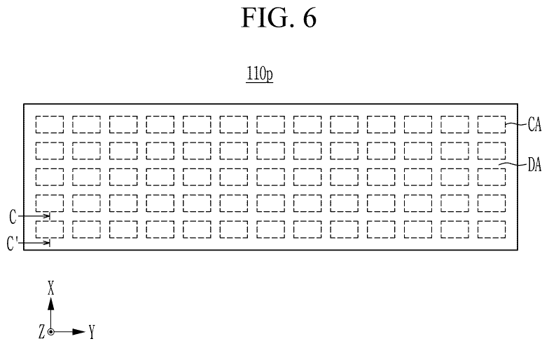

An embodiment of a manufacturing method of a semiconductor package 100 will be described in detail with reference to FIG. 6 to FIG. 12. To the extent that an element is not described in detail below, it may be understood that the element is at least similar to a corresponding element that has been described elsewhere within the present disclosure. A portion which is not described in the above will be described in detail. In an embodiment, a manufacturing method of a semiconductor package 100 may include a manufacturing method of a wiring substrate 110 included in the semiconductor package 100.

FIG. 6 to FIG. 12 illustrate stages in a manufacturing method of a semiconductor package according to an embodiment.

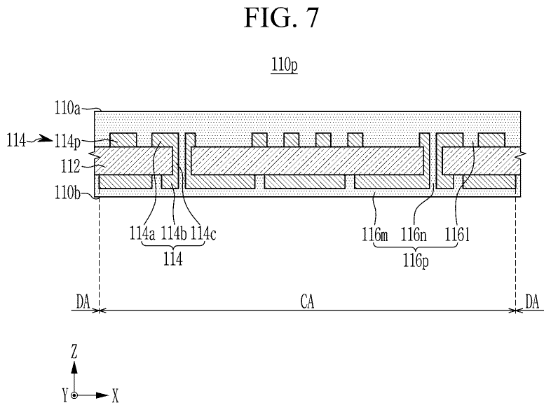

FIG. 6 is a plan view schematically illustrating a preliminary wiring substrate 110p before a molding process is performed according to an embodiment. FIG. 7 is a cross-sectional view taken along line C-C′ of FIG. 6. The preliminary wiring substrate 110p may refer to a structure before a solder resist layer 116 of a final structure is formed, or a structure before being cut into an individual wiring substrate 110 or an individual semiconductor package 100. The use of the term preliminary wiring substrate 110p may provide a clear understanding, but it will be understood that the descriptions associated with preliminary wiring substrate 110p will apply to a wiring substrate 110 unless context indicates otherwise.

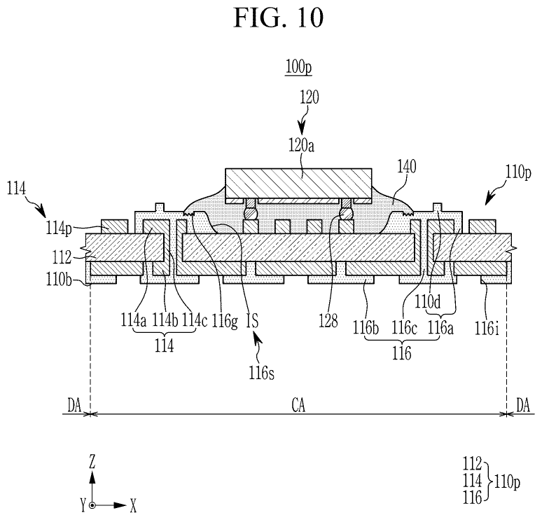

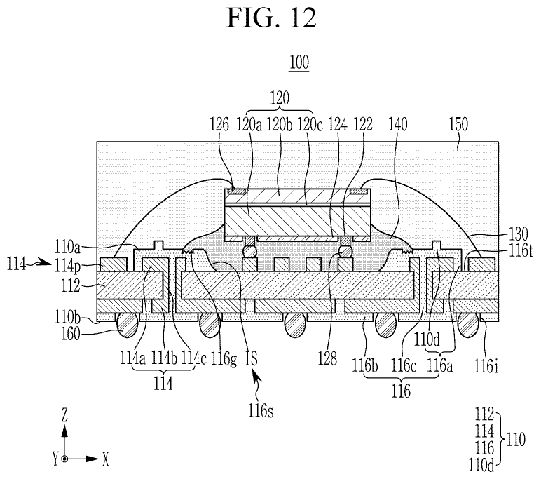

Referring to FIG. 6 and FIG. 7, a preliminary wiring substrate 110p according to an embodiment may include chip areas CA, which are areas where a plurality of semiconductor chips 120 (refer to FIG. 10) will be positioned, and a cut area DA. Before the molding process, the preliminary wiring substrate 110p or the wiring substrate 110 might not be provided with an external interconnection member 160 (refer to FIG. 12).

The chip area CA may be an area where the at least one semiconductor chip 120 is coupled or bonded with a flip chip structure by an interconnection member 128 (refer to FIG. 10). The cut area DA may refer to an area set to include a scribed portion or a cut portion when dividing the preliminary wiring substrate 110p including a plurality of chip areas CA into individual chip areas CA. The cut area DA may be referred to as a scribe lane, a scribe line, an outer area, an external area, or so on. The cut area DA may be at an edge of the chip area CA to form a boundary of the chip area CA.

For example, a plurality of chip areas CA may be in a first direction (an X-axis direction in the drawing) to form one row, and a plurality of rows of chip areas CA may be in a second direction (a Y-axis direction in the drawing) that is transverse to the first direction. The cut area DA may include a plurality of first cut areas longitudinally extending in the first direction and a plurality of second cut areas longitudinally extending in the second direction. Thereby, a structure of the cut area DA may be simplified. However, the embodiments are not limited thereto, and the first cut area and/or the second cut area may have a bent portion, a folded portion, a rounded portion, or so on according to an arrangement of the plurality of chip areas CA.

In FIG. 6, it is illustrated as an example that a short axis direction of the chip area CA is parallel to a short axis direction of the preliminary wiring substrate 110p, and a long axis direction of the chip area CA is parallel to a long axis direction of the preliminary wiring substrate 110p. However, the embodiments are not limited thereto. The short axis direction or the long axis direction of the chip area CA or the at least one semiconductor chip 120, the short axis direction or the long axis direction of the preliminary wiring substrate 110p, or so on may be variously modified.

The preliminary wiring substrate 110p may include a base member 112, and a wiring pattern 114 and a preliminary solder resist layer 116p on the base member 112. The preliminary solder resist layer 116p may include a first preliminary resist portion 1161 and a second preliminary resist portion 116m. The first preliminary resist portion 1161 may be on a first wiring portion 114a on a first surface of the base member 112 or be at a side of a first surface 110a of the preliminary wiring substrate 110p. The second preliminary resist portion 116m may be on a second wiring portion 114b on a second surface of the base member 112 or be at a side of a second surface 110b of the preliminary wiring substrate 110p. In the drawing, it is illustrated as an example that the solder resist layer 116 includes a preliminary through resist portion 116n at an inside of a through contact or an extension portion 114c, but the embodiments are not limited thereto.

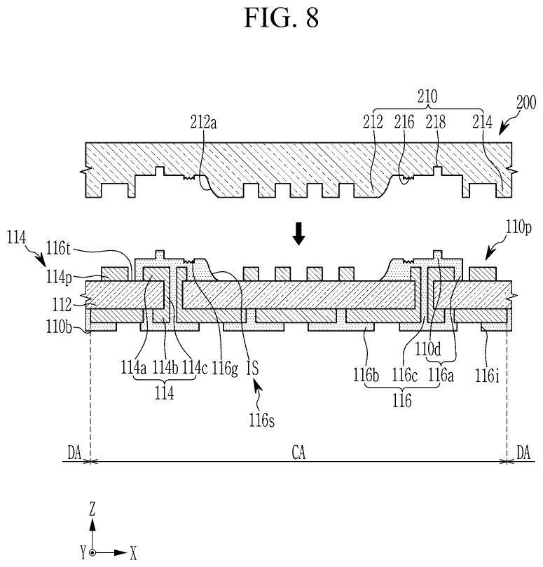

In this instance, the first preliminary resist portion 1161 may be formed to entirely cover the first surface of the base member 112 and might not have an opening area 116s (refer to FIG. 8) and/or an outer area 116t (refer to FIG. 8). The second preliminary resist portion 116m might not have an opening 116i (refer to FIG. 8) corresponding to an external interconnection member 160.

The preliminary solder resist layer 116p may be formed by applying an ink material including a solder resist material or placing a film including a solder resist material.

FIG. 8 illustrates a patterning process of the preliminary solder resist layer included in the manufacturing method of the semiconductor package according to an embodiment.

As illustrated in FIG. 8, a patterning process may be performed to the preliminary solder resist layer 116p (refer to FIG. 7) to form a solder resist layer 116 including a first resist portion 116a having an opening (e.g., an opening area 116s), an outer area 116t, an uneven portion 116g, and a dam 110d. In this instance, in the patterning process, a rounding process in which an inner surface IS of the first resist portion 116a adjacent to the opening area 116s is rounded to have a curved surface may be performed.

For example, the patterning process may be performed by an imprint lithography process, for example, a nanoimprint lithography process.

More particularly, in a state that a mold 200 having a pattern structure 210 may be placed on the first surface 110a (refer to FIG. 7) of the preliminary wiring substrate 110p and pressure is applied to the mold 200 toward the preliminary wiring substrate 110p, the preliminary solder resist layer 116p may be cured or hardened by an exposure process. The exposure process may be performed using heat, ultraviolet rays, or so on. As a result, the preliminary solder resist layer 116p is cured or hardened to have a predetermined shape by the pattern structure 210 to form the solder resist layer 116. In some embodiments, an etching process, for example, reactive ion etching (RIE), may be further performed to remove a material remaining in the solder resist layer 116.

The pattern structure 210 may be provided on a surface of the mold 200 facing the first surface 110a of the preliminary wiring substrate 110p. The pattern structure 210 may have a shape opposite to the opening area 116s, the outer area 116t, the uneven portion 116g, the dam 110d, and an inner surface IS having a curved surface to form the opening area 116s, the outer area 116t, the uneven portion 116g, the dam 110d, and the inner surface IS. That is, the pattern structure 210 may include a protruding portion to correspond to a portion to be an indentation portion in the preliminary wiring substrate 110p and may include an indentation portion to correspond to a portion to be a protruding portion in the preliminary wiring substrate 110p.

For example, the pattern structure 210 may have a first protruding portion 212 corresponding to the opening area 116s, and a side surface 212a of the first protruding portion 212 may have a curved surface. After the patterning process, the opening area 116s may be formed by the first protruding portion 212, and the inner surface IS of the first resist portion 116a may have a curved surface by the side surface 212a of the first protruding portion 212. The pattern structure 210 may have a second protruding portion 214 (a second protruding portion) corresponding to the outer area 116t. After the patterning process, the outer area 116t may be formed by the second protruding portion 214. The pattern structure 210 may have an uneven structure 216 corresponding to the uneven portion 116g. After the patterning process, the uneven portion 116g may be formed by the uneven structure 216. The pattern structure 210 may have an indentation portion 218 corresponding to the dam 110d. After the patterning process, the dam 110d may be formed by the indentation portion 218.

In an embodiment, in the process of patterning the preliminary solder resist layer 116p or the process of forming the solder resist layer 116, the process of forming the opening area 116s, the outer area 116t, the uneven portion 116g, and the dam 110d, and the rounding process of the inner surface IS of the first resist portion 116a may be performed together. That is, according to the embodiment, the process of forming the solder resist layer 116 may be simplified.

In the process of patterning the preliminary solder resist layer 116p, an opening 116i may be formed at the second resist portion 116b. The opening 116i may be formed by the same patterning process as the process of patterning the first resist portion 116a or may be formed by a separate patterning process different from the process of patterning the first resist portion 116a.

The description with reference to FIG. 6 to FIG. 8 in the above may correspond to a manufacturing method of the wiring substrate 110 included in the semiconductor package 100.

FIG. 9 illustrates a process of forming an underfill layer 140 included in the manufacturing method of the semiconductor package 100 according to an embodiment. FIG. 10 is a cross-sectional view illustrating a preliminary structure 100p on which the underfill layer 140 is formed. For simple illustration and a clear understanding, in FIG. 9, the preliminary wiring substrate 110p is illustrated as a simple structure, and the uneven portion 116g and the dam 110d are mainly illustrated. The preliminary structure 100p is a structure in which at least a partial portion of the at least one semiconductor chip 120 is on the preliminary wiring substrate 110p and is a structure before the semiconductor package 100 of the final structure is formed or before being cut into an individual semiconductor package 100.

As illustrated in FIG. 9 and FIG. 10, a at least one semiconductor chip 120 (more particularly, a first semiconductor chip 120a) is mounted on the preliminary wiring substrate 110p using a flip chip type, and then, an underfill process may be performed by supplying an underfill material to a space between the preliminary wiring substrate 110p and the at least one semiconductor chip 120.

For example, the underfill process (in the process of forming the underfill layer 140) may be performed by a dispensing process. For example, an underfill material 142 filled in a dispenser 220 may be pressed by a pressing member 222 and thus may be injected between the preliminary wiring substrate 110p and the at least one semiconductor chip 120. In this instance, a nozzle 224 of the dispenser 220 may be between the at least one semiconductor chip 120 and the uneven portion 116g of the first resist portion 116a in the preliminary wiring substrate 110p. That is, the uneven portion 116g of the first resist portion 116a may be at a rear portion of the nozzle 224. Accordingly, the underfill material 142 may be supplied between the at least one semiconductor chip 120 and the uneven portion 116g.

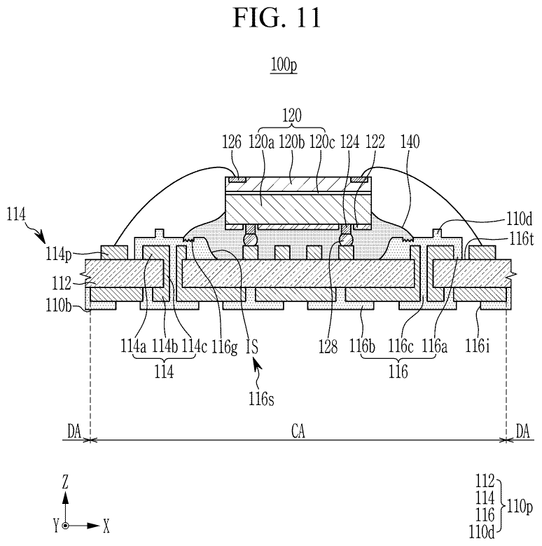

FIG. 11 a cross-sectional view illustrating a preliminary structure 100p including the at least one semiconductor chip 120 having the first semiconductor chip 120a and a second semiconductor chip 120b. The at least one semiconductor chip 120 having the first semiconductor chip 120a and the second semiconductor chip 120b may be formed by performing a bonding process and a wire bonding process included in the manufacturing method of the semiconductor package 100 according to an embodiment.

As illustrated in FIG. 11, a second semiconductor chip 120b may be bonded to the first semiconductor chip 120a using an adhesive layer 120c, and a wire bonding process for forming a connecting member 130 may be performed. In the wire bonding process, the connecting member 130 may be attached to a chip pad 126 of the second semiconductor chip 120b and a connection pad 114p of the preliminary wiring substrate 110p, respectively.

In FIG. 9 to FIG. 11, it is illustrated as an example that the first semiconductor chip 120a is bonded to the preliminary wiring substrate 110p, the underfill layer 140 is formed, the second semiconductor chip 120b is bonded to the first semiconductor chip 120a, and the wire bonding process for forming the connecting member 130 is performed. However, the embodiments are not limited thereto. In some embodiments, at least one semiconductor chip 120, in which a second semiconductor chip 120b is bonded to a first semiconductor chip 120a, is bonded to the preliminary wiring substrate 110p, and then, a process of forming the underfill layer 140 and the wire bonding process are performed. Various other modifications are possible.

FIG. 12 is a plan view illustrating the semiconductor package 100 in which a molding portion 150 and an external interconnection member 160 are formed by performing a process of forming the molding portion 150 and the external interconnection member 160 and a cutting process.

As illustrated in FIG. 12, a molding portion 150 may be formed through a molding process, an external interconnection member 160 may be formed, and a cutting process may be performed to form a plurality of individual semiconductor packages 100. Any of various processes may be applied as the molding process, a process of forming the external interconnection member 160, or the cutting process. For example, in the cutting process of cutting the preliminary structure 100p (refer to FIG. 11), the preliminary structure 100p may be cut along the cut area DA (refer to FIG. 11) between a plurality of chip areas CA (refer to FIG. 11) to form a plurality of semiconductor packages 100.

According to an embodiment, in the process of forming the underfill layer 140, the contact surface area between the solder resist layer 116 and the underfill layer 140 may be increased by the uneven portion 116g, thereby improving a physical bonding force between the solder resist layer 116 and the underfill layer 140. The underfill material may be locked in the uneven portion 116g and may be prevented from overflowing to the outside of the dam 110d. The uneven portion 116g at the rear portion of the nozzle 224 of the dispenser 220 may guide the underfill material to flow in an internal direction (i.e., toward a lower portion of the at least one semiconductor chip 120) rather than in an external direction (i.e., toward the dam 110d). The inner surface IS of the first resist portion 116a adjacent to the opening area 116s may have a curved surface to allow the underfill material 142 to flow stably. Accordingly, productivity and reliability of the process of forming the underfill layer 140 may be improved, and reliability of the semiconductor package 100 formed thereby may be improved.

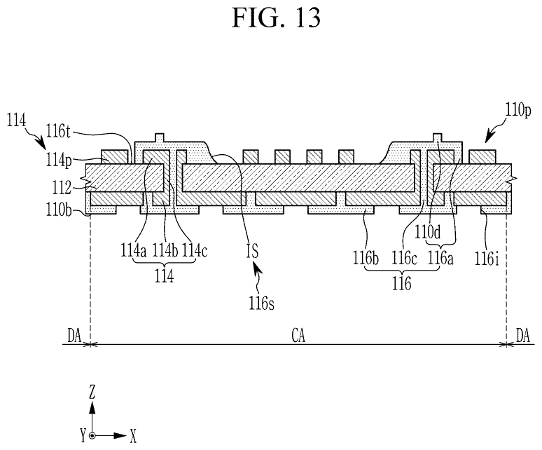

Hereinafter, a manufacturing method of a semiconductor package according to an embodiment different from the previous embodiment, and a semiconductor package and a wiring substrate included in the semiconductor package will be described in more detail with reference to FIGS. 13 to 18. To the extent that an element is not described in detail below, it may be understood that the element is at least similar to a corresponding element that has been described elsewhere within the present disclosure. A portion which is not described in the above will be described in detail.

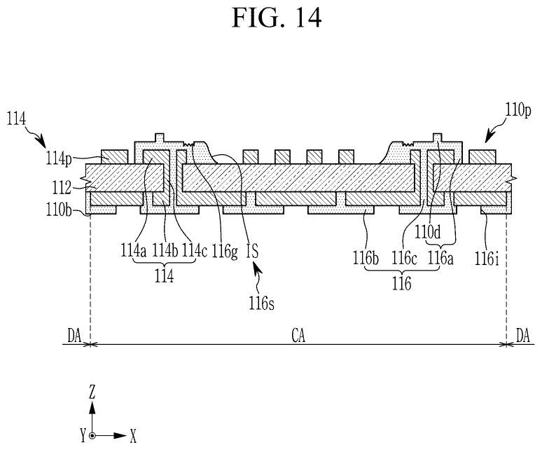

FIG. 13 and FIG. 14 illustrate a manufacturing method of a semiconductor package according to an embodiment. FIG. 13 illustrates a patterning process of a preliminary solder resist layer included in a manufacturing method of a semiconductor package according to an embodiment. FIG. 14 illustrates a process for forming an uneven portion at a solder resist layer.

As illustrated in FIG. 13, a patterning process may be performed to a preliminary solder resist layer 116p (refer to FIG. 7) to form a solder resist layer 116 including a first resist portion 116a having an opening (e.g., an opening area 116s), an outer area 116t, and a dam 110d. In this instance, in the patterning process, a rounding process may be performed in which an inner surface IS of the first resist portion 116a adjacent to the opening area 116s is rounded to have a curved surface. Unlike the previous embodiment, the solder resist layer 116 might not have an uneven portion 116g.

The description with reference to FIG. 7 may be applied as it is to the preliminary wiring substrate 110p including the preliminary solder resist layer 116p, except for the uneven portion 116g.

In some embodiments, the patterning process may be performed by an imprint lithography process, for example, a nanoimprint lithography process. Except that a pattern structure 210 (refer to FIG. 8) of a mold 200 (refer to FIG. 8) does not have an uneven structure 216 (refer to FIG. 8) and the uneven portion 116g is not formed in the patterning process, the description referring to FIG. 8 may be applied as it is to the patterning process.

In some embodiments, the patterning process may be performed by a scanning probe lithography (SPL) process. By the scanning probe lithography process, in the patterning process of forming the solder resist layer 116 including the first resist portion 116a having the opening (e.g., the opening area 116s), the outer area 116t, and the dam 110d, and the rounding process of rounding the inner surface IS of the first resist portion 116a to have the curved surface may be easily performed.

In some embodiments, in the patterning process, an exposure process may be performed to form the solder resist layer 116 having the opening area 116s, the outer area 116t, and the dam 110d. For example, a partial portion (e.g., an upper portion) in a thickness direction may be exposed in an area other than the dam 110d, the opening area 116s, and the outer area 116t, and an entire portion in the thickness direction may be exposed in an area corresponding to the opening area 116s and the outer area 116t. The exposed portion may be removed in a development process to form the opening area 116s, the outer area 116t, and the dam 110d. In this instance, in the developing process, the rounding process is performed to round the inner surface IS of the first resist portion 116a to have the curved surface by adjusting a speed of the developing material (e.g., developer or a developing solution) and a number of development processes.

Subsequently, as illustrated in FIG. 14, an etching process may be performed at the solder resist layer 116 to form an uneven portion 116g. For example, the uneven portion 116g may be formed by a dry etching process (e.g., a plasma etching process or a reactive ion etching process) or a wet etching process. The process of forming the uneven portion 116g may be variously modified.

The description with reference to FIG. 13 and FIG. 14 may correspond to a manufacturing method of the wiring substrate 110 included in the semiconductor package 100. The description referring to FIG. 9 to FIG. 12 may be applied as it is to the manufacturing method of the semiconductor package 100 using the wiring substrate 110.

According to an embodiment, the uneven portion 116g may be formed separately through an additional process. Then, the manufacturing method may be applied to the preliminary wiring substrate 110p or the wiring substrate 110 having the solder resist layer 116 to form the uneven portion 116g.

In the above description, the rounding process is performed to round the inner surface IS of the first resist portion 116a to have the curved surface, but the rounding process might not be performed in some embodiments.

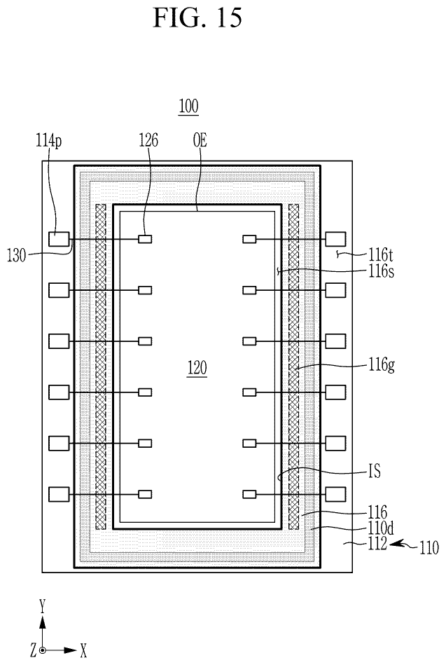

FIG. 15 is a plan view schematically illustrating a semiconductor package according to an embodiment. FIG. 15 illustrates a portion corresponding to FIG. 1.

Referring to FIG. 15, in an embodiment, a pair of uneven sections may be at both sides of the at least one semiconductor chip 120 in one direction to be spaced apart from both edges of the at least one semiconductor chip 120 in the one direction. The pair of uneven sections may have shapes that longitudinally extend in a transverse direction that is transverse to (for example, perpendicular to) the one direction. For example, distances between the both edges of the at least one semiconductor chip 120 and the pair of uneven sections may be the same, and lengths of the pair of uneven sections in the transverse direction that is transverse the one direction may be the same. However, the embodiments are not limited thereto, and various modifications are possible. For example, the uneven section may be partially formed rather than continuously formed in the transverse direction.

In the process of forming the underfill layer 140 where the underfill material is injected in one direction, the pair of uneven sections may be at a first side and a second side of the at least one semiconductor chip 120 opposite to each other in one direction. In some embodiments, the pair of uneven sections may be applied to the process forming the underfill layer 140 where the underfill materials are injected in two directions that are transverse to each other.

In FIG. 15, the pair of uneven sections are at both edges in the first direction (the X-axis direction in the drawing), and no uneven sections are at both edges in the second direction (the Y-axis direction in the drawing). However, the embodiments are not limited thereto. In some embodiments, a pair of uneven sections are at both edges in the second direction (the Y-axis direction in the drawing), and no uneven sections are at both edges in the first direction (the X-axis direction in the drawing).

In FIG. 15, it is illustrated as an example that the pair of uneven sections are at both edges in a short axis direction, and no uneven sections are at both edges in a long axis direction. However, the embodiments are not limited thereto. In some embodiments, a pair of uneven sections may be at both edges in a long axis direction, but no uneven sections may be at both edges in a short axis direction.

In FIG. 15, it is illustrated as an example that the uneven portion is at an edge portion between at least one semiconductor chip 120 and the connection pad 114p, and the uneven section is not at an edge portion where the connection pad 114p is not positioned. According to this, the underfill material 142 may be effectively prevented from overflowing and contaminating the connection pad 114p in the process of forming the underfill layer 140. However, the embodiments are not limited thereto.

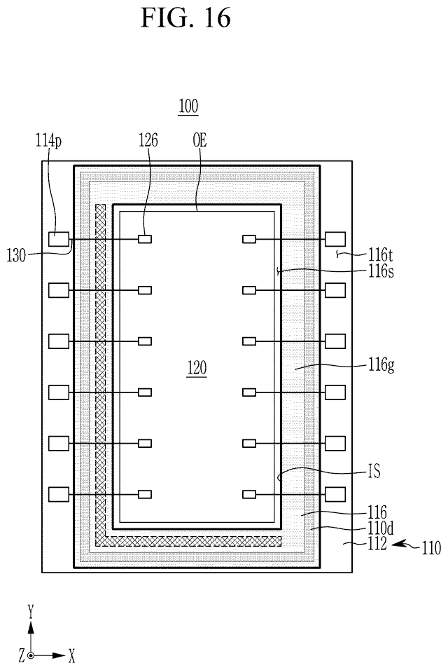

FIG. 16 is a plan view schematically illustrating a semiconductor package according to an embodiment. FIG. 15 illustrates a portion corresponding to FIG. 1.

Referring to FIG. 16, in a semiconductor package 100 according to an embodiment, in one direction, an uneven portion 116g may include one uneven section spaced apart from one edge of the at least one semiconductor chip 120 at one side of the at least one semiconductor chip 120. The uneven section may have a shape that longitudinally extends in a transverse direction that is transverse to (e.g., perpendicular to) the one direction.

For example, in one direction, an uneven portion 116g may be at one of a first side where an underfill material is injected in a process of forming an underfill layer and a second side that is opposite to the first side but might not be at the other of the first side and the second side. For example, the uneven portion 116g may be at the first side where the underfill material is injected in the process of forming the underfill layer, thereby preventing the underfill material from flowing in an external direction. In some embodiments, the uneven portion 116g may be at the second side opposite to the first side where the underfill material is injected in the process of forming the underfill layer. Thereby, the underfill material flowing to the second side may be prevented from flowing over the dam 110d and flowing to an outside.

In FIG. 16, it is illustrated as an example that the uneven portions 116g or the uneven sections are in each of the first and second directions that are transverse to each other and are in a short axis direction and a long axis direction that are transverse to each other. It is illustrated as an example that the uneven portion 116g or the uneven section extending in the first direction and the uneven portion 116g or the uneven section extending in the second direction may be connected at a corner portion. However, the embodiments are not limited thereto.

In some embodiments, the uneven portion 116g or the uneven section may be at one side of the at least one semiconductor chip 120 or the dam 110d in the first direction and might not be at both sides of the at least one semiconductor chip 120 or the dam 110d in the second direction. In some embodiments, the uneven portion 116g or the uneven section may be at one side of the at least one semiconductor chip 120 or the dam 110d in the second direction and might not be at both sides of the at least one semiconductor chip 120 or the dam 110d in first second direction. In some embodiments, the uneven portion 116g or the uneven section may be at one side of the at least one semiconductor chip 120 or the dam 110d in the first direction and the uneven portions 116g or the uneven sections may be at both sides of the at least one semiconductor chip 120 or the dam 110d in the second direction. In some embodiments, the uneven portion 116g or the uneven section may be at one side of the at least one semiconductor chip 120 or the dam 110d in the second direction and the uneven portions 116g or the uneven sections may be at both sides of the at least one semiconductor chip 120 or the dam 110d in the first direction. Various other modifications are possible.

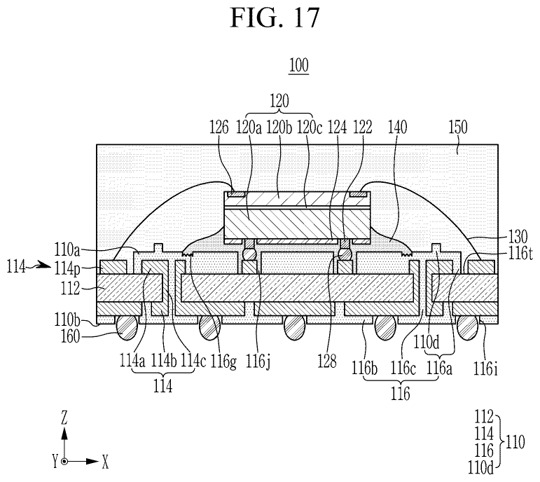

FIG. 17 is a cross-sectional view illustrating a semiconductor package according to an embodiment. FIG. 17 illustrates a portion corresponding to FIG. 2.

Referring to FIG. 17, in a semiconductor package 100 according to an embodiment, an opening exposing at least a partial portion of a first wiring portion 114a in a first resist portion 116a may include an opening 116j exposing a portion where the interconnection member 128 is connected. A plurality of openings 116j may correspond to a plurality of interconnection members 128 (e.g., in a one-to-one arrangement). Accordingly, the first resist portion 116a may have a relatively large area and may more stably protect the first wiring portion 114a.

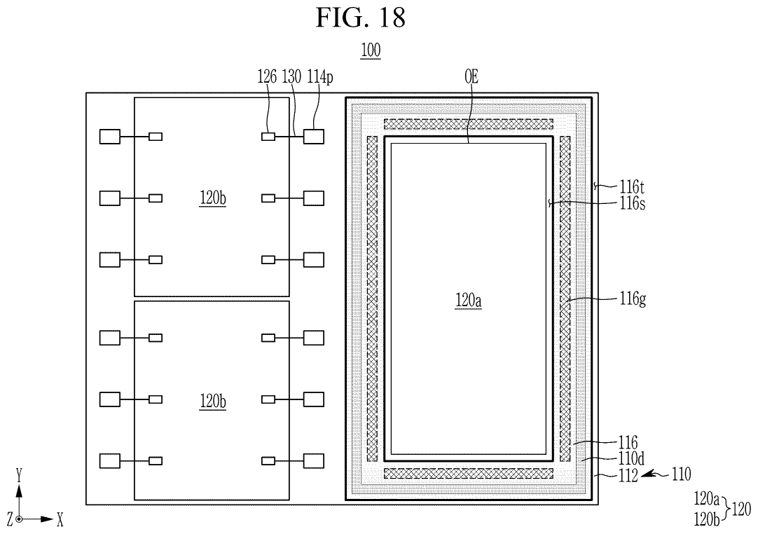

FIG. 18 is a plan view schematically illustrating a semiconductor package according to an embodiment. FIG. 18 illustrates a portion corresponding to FIG. 1.

Referring to FIG. 18, in the embodiment, a first semiconductor chip 120a may correspond to an opening of the solder resist layer 116, and a second semiconductor chip 120b may be separately positioned from the first semiconductor chip 120a in a plan view. For example, the first semiconductor chip 120a may be within an opening area 116s of a first resist portion and the second semiconductor chip 120b may be in an outer area 116t of the first resist portion. Accordingly, the first semiconductor chip 120a and the second semiconductor chip 120b may be separated in a plan view and thus be formed through an easy manufacturing process.

In FIG. 18, it is illustrated as an example that the second semiconductor chip 120b is electrically connected to the wiring substrate 110 by wire bonding using a connecting member 130, but the embodiments are not limited thereto. The second semiconductor chip 120b may be connected to the wiring substrate 110 with a flip chip structure by another interconnection member. In this instance, another underfill layer may be provided between the first resist portion 116a of the wiring substrate 110 and the second semiconductor chip 120b, and another uneven portion may be provided in a portion corresponding to the second semiconductor chip 120b. The description of the uneven portion 116g corresponding to the first semiconductor chip 120a may be applied to another uneven portion corresponding to the second semiconductor chip 120b.

In FIG. 18, it is illustrated as an example that the second semiconductor chip 120b has a smaller size or area than the first semiconductor chip 120a, but the embodiments are not limited thereto. The second semiconductor chip 120b may have a size or area that is the same as or greater than that of the first semiconductor chip 120a. In FIG. 18, it is illustrated as an example that a number of second semiconductor chips 120b is greater than a number of first semiconductor chips 120a, but the embodiments are not limited thereto. The number of second semiconductor chips 120b may be the same as or less than the number of first semiconductor chips 120a.

While some examples have been described in connection with what is presently considered to be some practical embodiments, it is to be understood that the disclosure is not limited to the disclosed embodiments, and that that the disclosure is intended to cover various modifications and equivalent arrangements included within the spirit and scope of the appended claims.

What is claimed is:

1. A semiconductor package, comprising:
a wiring substrate having a first surface and a second surface opposite to each other;
a semiconductor chip connected to the wiring substrate and positioned on the first surface of the wiring substrate; and
an underfill layer between the wiring substrate and the semiconductor chip,
wherein the wiring substrate includes a wiring pattern, a solder resist layer including an opening exposing a portion of the wiring pattern at the first surface and a dam protruding away from the wiring substrate at a region external to a lateral extent of the semiconductor chip at the first surface,
the solder resist layer further includes an uneven portion at a surface of the solder resist layer between the dam and the opening, and
the uneven portion is between the semiconductor chip and the dam in a plan view.

2. The semiconductor package of claim 1, wherein a surface roughness of the uneven portion is greater than a surface roughness of a portion of the solder resist layer other than the uneven portion, and
a lower surface of the uneven portion is lower than an upper surface of the portion of the solder resist layer other than the uneven portion.

3. The semiconductor package of claim 1, wherein the uneven portion is spaced apart from an edge of the semiconductor chip in a plan view.

4. The semiconductor package of claim 1, wherein the uneven portion is spaced apart from an inner edge of the dam or adjacent to the inner edge of the dam in a plan view.

5. The semiconductor package of claim 1, wherein a width of the uneven portion is greater than a depth of the uneven portion.

6. The semiconductor package of claim 1, wherein a width of the uneven portion is greater than a width of the dam.

7. The semiconductor package of claim 1, wherein the opening is an opening area having an area greater than an area of the semiconductor chip to include an entire area of the semiconductor chip in a plan view, and
an inner edge of the uneven portion is spaced apart from an inner edge of the solder resist layer adjacent to the opening area at the surface of the solder resist layer at the first surface.

8. The semiconductor package of claim 7, wherein, in a plan view, a distance between the inner edge of the uneven portion and the inner edge of the solder resist layer is greater than a distance between an outer edge of the uneven portion and the dam.

9. The semiconductor package of claim 1, wherein the opening is an opening area having an area greater than an area of the semiconductor chip in a plan view, and
an inner surface of the solder resist layer adjacent to the opening area includes a curved surface.

10. The semiconductor package of claim 1, wherein the dam is part of the solder resist layer.

11. The semiconductor package of claim 1, wherein the uneven portion is only at one side of the solder resist layer in a plan view.

12. The semiconductor package of claim 1, wherein, in a plan view, the uneven portion includes a plurality of uneven sections at both sides of the solder resist layer in a first direction and each uneven section of the plurality of uneven sections is spaced apart from an adjacent uneven section in the first direction and extends in a second direction that is transverse to the first direction.

13. A wiring substrate having a first surface and a second surface opposite to each other, wherein the wiring substrate includes a wiring pattern, a solder resist layer including an opening exposing a portion of the wiring pattern at the first surface, and a dam protruding away from the wiring substrate at a region external to a lateral extent of the opening at the first surface,
the solder resist layer further includes an uneven portion at a surface of the solder resist layer between the dam and the opening, and
the uneven portion is within the dam in a plan view.

14. A manufacturing method of a semiconductor package, comprising:
forming a solder resist layer on a wiring substrate, the solder resist layer including an opening, a dam, and an uneven portion between the opening and the dam in a plan view; and
forming an underfill layer through supplying an underfill material between a semiconductor chip and the dam in a state in which the semiconductor chip and the wiring substrate are bonded using an interconnection member.

15. The manufacturing method of claim 14, wherein, in a plan view, the uneven portion is between the semiconductor chip and the dam, and
in the forming of the underfill layer, the underfill material is supplied between the semiconductor chip and the uneven portion.

16. The manufacturing method of claim 14, wherein, in the forming of the solder resist layer, the opening, the dam, and the uneven portion are formed together using an imprint lithography process.

17. The manufacturing method of claim 14, wherein the forming of the solder resist layer includes:
forming the solder resist layer including the opening and the dam using a lithography process; and
forming the uneven portion by performing an etching process on the solder resist layer.

18. The manufacturing method of claim 17, wherein the etching process is performed by dry etching or wet etching.

19. The manufacturing method of claim 14, wherein the opening is an opening area having an area greater than an area of the semiconductor chip in a plan view, and
the forming of the solder resist layer includes a rounding process of rounding an inner surface of the solder resist layer adjacent to the opening area to have a curved surface.

20. The manufacturing method of claim 19, wherein, in the forming of the solder resist layer, a process of forming the opening area, the dam, and the uneven portion and the rounding process are performed together using an imprint lithography process.
